(19) United States
(12) Patent Application Publication
(10) Pub. No.: US 2025/0072196 A1
(43) Pub. Date: Feb. 27, 2025

(54) RESONANT CAVITY LIGHT-EMITTING DIODE, MANUFACTURING METHOD THEREOF, AND LIGHT-EMITTING ARRAY STRUCTURE

(71) Applicant: ENKRIS SEMICONDUCTOR, INC., Suzhou (CN)

(72) Inventor: Kai CHENG, Suzhou (CN)

(73) Assignee: ENKRIS SEMICONDUCTOR, INC., Suzhou (CN)

(21) Appl. No.: 18/796,825

(22) Filed: Aug. 7, 2024

(30) Foreign Application Priority Data
Aug. 23, 2023 (CN) 202311068399.2

(51) Int. Cl. H01L 33/46; H01L 27/15; H01L 33/00; H01L 33/24; H01L 33/38

(52) U.S. Cl. CPC H01L 33/465; H01L 27/15; H01L 33/0093; H01L 33/24; H01L 33/382; H01L 2933/0025

(57) ABSTRACT

A manufacturing method of a resonant cavity light-emitting diode includes: epitaxially forming a first type semiconductor layer in a window with a relatively smaller area; epitaxially forming an active layer, a second type semiconductor layer and a first reflective layer on the first type semiconductor layer, placing them upside down on a carrier substrate, in a direction away from the carrier substrate, the area of the first type semiconductor layer gradually decreasing; and forming a second reflective layer on a sloped wall of the first type semiconductor layer. An upper surface on a side, away from the carrier substrate, of the first type semiconductor layer is a light outlet.

### CROSS-REFERENCE TO RELATED APPLICATIONS

This application claims priority to Chinese Patent Application No. 202311068399.2, filed on Aug. 23, 2023, the content of which is incorporated herein by reference in its entirety.

### TECHNICAL FIELD

The present disclosure relates to the technical field of semiconductors, in particular to a resonant cavity light-emitting diode, a manufacturing method thereof, and a light-emitting array structure.

### BACKGROUND

With the development of big data and the fifth-generation mobile communication technology, the information processing of optical network continues to increase, and the high-density broadband communication continues to improve. Resonant cavity light-emitting diode (RCLED) and vertical cavity surface emitting lighter (VCSEL) as laser light sources have attracted more and more attention.

In the laser light sources, a porous oxide layer is often used to laterally control over electrons and photons. However, due to high complexity and poor stability of the oxidation process, it is difficult to accurately control an oxidation depth; moreover, there is a difference in the thermal expansion coefficient between oxide and semiconductor. Stress is generated at the pores of the oxide layer, which reduces the reliability of a device.

### SUMMARY

In view of this, a resonant cavity light-emitting diode, a manufacturing method thereof, and a light-emitting array structure are provided in the embodiments of the present disclosure, so as to solve the technical problem of low device reliability in traditional technology.

According to one aspect of the present disclosure, a manufacturing method of a resonant cavity light-emitting diode is provided, including: forming a patterned mask layer on a growth substrate, where the patterned mask layer has a window exposing the growth substrate, along an arrangement direction of the growth substrate and the patterned mask layer, a cross-sectional area of the window gradually increases; epitaxially forming a first type semiconductor layer in the window; epitaxially forming an active layer, a second type semiconductor layer and a first reflective layer on the first type semiconductor layer; placing the growth substrate, the patterned mask layer, the first type semiconductor layer, the active layer, the second type semiconductor layer and the first reflective layer upside down on a carrier substrate; removing the growth substrate and the patterned mask layer, where along an arrangement direction of the carrier substrate and the first type semiconductor layer, a cross-sectional area of the first type semiconductor layer gradually decreases; the first type semiconductor layer includes a sloped wall and an upper surface on a side away from the carrier substrate, and the sloped wall matches a shape of the window; and forming a second reflective layer on the sloped wall, the upper surface being a light outlet.

According to another aspect of the present disclosure, a resonant cavity light-emitting diode manufactured by the above manufacturing method is provided, including: a first reflective layer, a second type semiconductor layer, an active layer and a first type semiconductor layer sequentially stacked on a carrier substrate; where the first type semiconductor layer includes a sloped wall and an upper surface on a side away from the carrier substrate, along an arrangement direction of the carrier substrate and the first type semiconductor layer, a cross-sectional area of the first type semiconductor layer gradually decreases; and a second reflective layer, at least covering the sloped wall, and the upper surface being a light outlet.

According to another aspect of the present disclosure, a light-emitting array structure is provided, including: a first light-emitting area and a second light-emitting area that are adjacent, where the first light-emitting area includes the above-mentioned resonant cavity light-emitting diodes; a pixel structure of the second light-emitting area includes any one of LED pixels, organic light emitting diode (OLED) pixels or liquid crystal display (LCD) pixels.

One of the above technical solutions has the following beneficial effects.

This disclosure provides a manufacturing method of a resonant cavity light-emitting diode. The cross-sectional area of the window of the patterned mask layer gradually increases. The first type semiconductor layer is first epitaxially formed on the growth substrate with a relatively smaller area, and then laterally epitaxially to fill the window, which reduce the dislocation density of the first type semiconductor layer, improve the crystal quality, and improve device reliability; and there is no need to use the process of etching the entire layer of the first type semiconductor layer to form a patterned unit, avoiding the etching process to the first type semiconductor layer, thereby ensuring that the crystal quality of the first type of semiconductor layer is not reduced; then the active layer, the second type semiconductor layer and the first reflective layer are epitaxially formed in sequence, and placed upside down on the carrier substrate. In the direction away from the carrying substrate, the area of the first type semiconductor layer gradually decreases, and a second reflective layer is formed on the sloped wall of the first type semiconductor layer. The first reflective layer and the second reflective layer form a resonant cavity, and the light is reflected multiple times in the resonant cavity to improve the resonance effect of the light, so that the light has a narrower wavelength peak, improving the spectral purity. The upper surface, away from the carrier substrate, of the first type semiconductor layer is a light outlet. The area of the light outlet is the smallest, which can improve the directionality and collimation of light emission.

### BRIEF DESCRIPTION OF THE DRAWINGS

FIG. 1 is a schematic flowchart of a manufacturing method of a resonant cavity light-emitting diode according to an embodiment of the present disclosure.

FIGS. 2-8 are schematic structural diagrams of a resonant cavity light-emitting diode according to an embodiment of the present disclosure.

FIG. 9 is a schematic structural diagram of a resonant cavity light-emitting diode according to another embodiment of the present disclosure.

FIG. 10 is a schematic structural diagram of a resonant cavity light-emitting diode according to another embodiment of the present disclosure.

FIG. 11 is a schematic structural diagram of a resonant cavity light-emitting diode according to another embodiment of the present disclosure.

FIG. 12 is a schematic structural diagram of a resonant cavity light-emitting diode according to another embodiment of the present disclosure.

FIG. 13 is a schematic structural diagram of a resonant cavity light-emitting diode according to another embodiment of the present disclosure.

FIG. 14 is a schematic structural diagram of a resonant cavity light-emitting diode according to another embodiment of the present disclosure.

FIG. 15 is a schematic structural diagram of a resonant cavity light-emitting diode according to another embodiment of the present disclosure.

FIG. 16 is a schematic structural diagram of a resonant cavity light-emitting diode according to another embodiment of the present disclosure.

FIG. 17 is a schematic structural diagram of a resonant cavity light-emitting diode according to another embodiment of the present disclosure.

FIG. 18 is a schematic three-dimensional structural diagram of a resonant cavity light-emitting diode according to an embodiment of the present disclosure.

FIG. 19 is a schematic structural diagram of a resonant cavity light-emitting diode according to another embodiment of the present disclosure.

FIG. 20 is a top view of the resonant cavity light-emitting diode provided in FIG. 12.

FIG. 21 is a schematic structural diagram of a resonant cavity light-emitting diode according to another embodiment of the present disclosure.

FIG. 22 is an arrangement diagram of resonant cavity light-emitting diodes according to an embodiment of the present disclosure.

FIG. 23 is an arrangement diagram of resonant cavity light-emitting diodes according to another embodiment of the present disclosure.

FIG. 24 is an arrangement diagram of resonant cavity light-emitting diodes according to another embodiment of the present disclosure.

FIG. 25 is a schematic structural diagram of a light-emitting array structure according to an embodiment of the present disclosure.

FIG. 26 is a schematic structural diagram of a light-emitting array structure according to another embodiment of the present disclosure.

FIG. 27 is a schematic structural diagram of a light emitting array structure according to another embodiment of the present disclosure.

### DETAILED DESCRIPTION OF THE EMBODIMENTS

The technical solutions in the embodiments of the present disclosure will be clearly described below in combination with the accompanying drawings in the embodiments of the present disclosure. Obviously, the described embodiments are only some of the embodiments of the present disclosure, not all of them. Based on the embodiments of the present disclosure, all other embodiments obtained by a person of ordinary skill in the art without forming creative efforts fall within the scope of protection of the present disclosure.

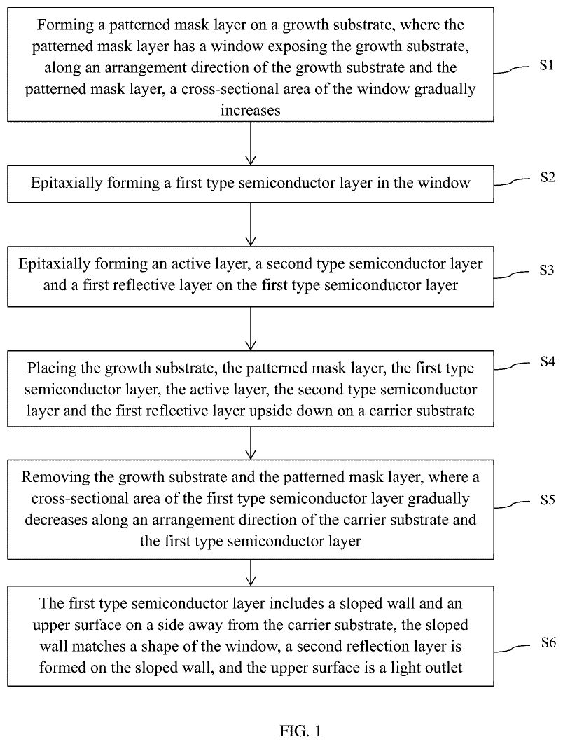

In order to improve the light extraction efficiency, FIG. 1 is a schematic flowchart of a manufacturing method of a resonant cavity light-emitting diode according to an embodiment of the present disclosure, and FIGS. 2-8 are schematic structural diagrams of a resonant cavity light-emitting diode according to an embodiment of the present disclosure. As shown in FIG. 1, the present disclosure provides a manufacturing method of a resonant cavity light-emitting diode, which includes following steps.

Step S1, as shown in FIG. 2, forming a patterned mask layer 12 on a growth substrate 11, where the patterned mask layer 12 has a window 121 exposing the growth substrate 11, along an arrangement direction of the growth substrate 11 and the patterned mask layer 12, a cross-sectional area of the window 121 gradually increases.

Specifically, the patterned mask layer 12 is SiO₂ or SiN, and the patterned structure is formed by photolithography to SiO₂ or SiN, and the cross-sectional area, parallel to a plane where the growth substrate 11 is located, of the window 121 left in the photolithographic region gradually increases.

Optionally, as shown in FIG. 2, a shape of a side wall of the window 121 is a curve protruding away from the growth substrate 11; optionally, the shape of the side wall of the window 121 is a curve that is concave toward the growth substrate, or a straight line.

Optionally, the growth substrate 11 includes any one of sapphire, silicon, silicon carbide, silicon germanium, GaN or GaAs.

It should be noted that FIG. 2 only shows three windows 121 for forming three resonant cavity light-emitting diodes; it should be understood that the number of resonant cavity light-emitting diodes is not limited in the embodiments of the present disclosure.

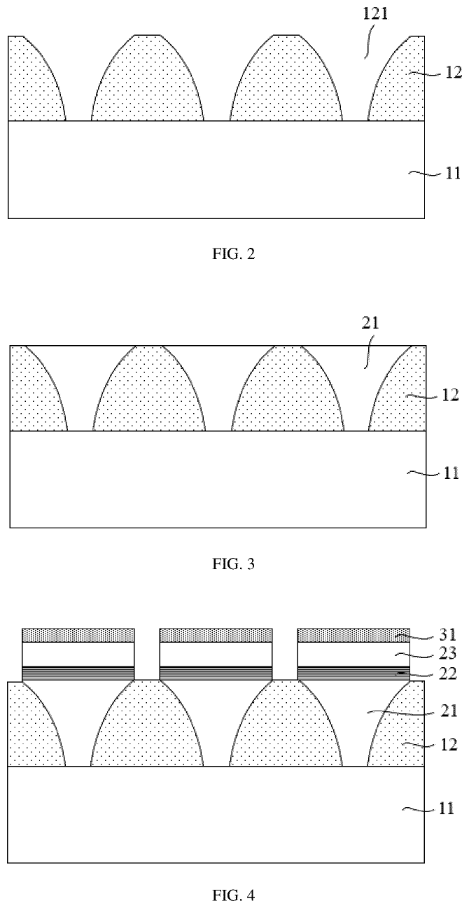

Step S2, as shown in FIG. 3, epitaxially forming a first type semiconductor layer 21 in the window 121. It should be noted that, in the direction away from the growth substrate 11, the cross-sectional area of the first type semiconductor layer 21 gradually increases, that is to say, the first type semiconductor layer 21 is first epitaxially grown on the growth substrate 11 with a smaller area, then laterally epitaxially to fill the window 121. Taking the material of the first type semiconductor layer 21 being GaN as an example, the dislocations in GaN are mainly linear dislocations along the crystal direction, that is, linear dislocations extending along the thickness direction of the growth substrate 11. At this time, the smaller of the epitaxial growth area of the first type semiconductor layer 21 is, the dislocation density of GaN can be reduced, thereby improving the crystal quality of the first type semiconductor layer 21. Moreover, the mask layer 12 is patterned by photolithography, which can control a specific shape of the first type semiconductor layer 21 to obtain a resonant cavity diode with the specific shape, and the process is relatively simple.

Optionally, before forming the first type semiconductor layer 21, a nucleation layer and a buffer layer are formed epitaxially at the bottom of the window 121. When the material of the first type semiconductor layer 21 is a GaN-based material, the material of the nucleation layer is AlN, and the material of the buffer layer is GaN.

Step S3, as shown in FIG. 4, epitaxially forming an active layer 22, a second type semiconductor layer 23 and a first reflective layer 31 on the first type semiconductor layer 21.

Optionally, when the material of the first type semiconductor layer 21 is a GaN-based material, the material of the active layer 22 includes a combination of any two of GaN, InGaN, AlGaN, and AlInGaN, and the material of the second type semiconductor layer 23 is a GaN-based material with an opposite conductivity type to the first type semiconductor layer 21.

Optionally, when the material of the first type semiconductor layer 21 and the material of the second type semiconductor layer 23 are GaAs-based materials, the material of the active layer 22 includes a combination of any two of GaAs, InGaAs, AlGaAs and AlInGaAs.

Optionally, when the material of the first type semiconductor layer 21 and the material of the second type semiconductor layer 23 are GaP-based materials, the material of the active layer 22 includes a combination of any two of GaP, InGaP, AlGaP and AlInGaP.

Optionally, the material of the first reflective layer 31 is metal or metal alloy with high reflectivity. Optionally, the material of the first reflective layer 31 is a distributed Bragg reflector composed of oxide material pairs such as TiO₂/SiO₂, Ti₃O₅/SiO₂, Ta₂O₅/SiO₂, Ti₃O₅/Al₂O₃, ZrO₂/SiO₂ or TiO₂/Al₂O₃.

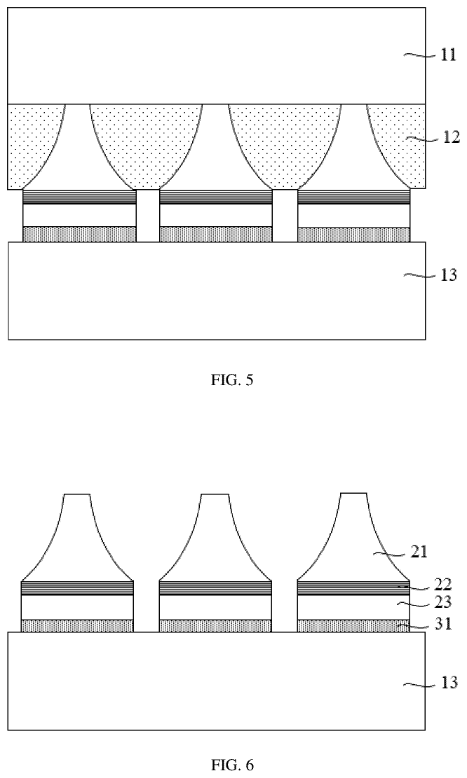

Step S4, as shown in FIG. 5, placing the growth substrate 11, the patterned mask layer 12, the first type semiconductor layer 21, the active layer 22, the second type semiconductor layer 23 and the first reflective layer 31 upside down on a carrier substrate 13.

Optionally, the carrier substrate 13 is a driving circuit board, including a driving circuit that provides driving signals for the finally produced resonant cavity light-emitting diode. Optionally, before Step S4, a second electrode electrically connected to the second type semiconductor layer 23 is formed; in Step S4, the second electrode is electrically connected to the driving circuit board (carrier substrate 13).

Step S5, as shown in FIG. 6, removing the growth substrate 11 and the patterned mask layer 12, where a cross-sectional area of the first type semiconductor layer 21 gradually decreases along an arrangement direction of the carrier substrate 13 and the first type semiconductor layer 21.

It should be noted that the shape of the first type semiconductor layer 21 formed in the window 121 is consistent with the shape of the window 121, therefore, the cross-sectional area of the first type semiconductor layer 21 gradually decreases in the direction away from the carrier substrate 13.

Optionally, the removal method of the growth substrate 11 is laser lift-off. Optionally, the removal method of the patterned mask layer 12 is etching.

In an embodiment, as shown in FIG. 7, after removing the growth substrate 11 and the patterned mask layer 12, the manufacturing method further includes: forming a passivation layer 41 on a side wall of the first type semiconductor layer 21, the active layer 22 and the second type semiconductor layer 23. Optionally, the material of the passivation layer 41 is an insulating material, such as SiO₂, Al₂O₃, SiN, polyimide, photoresist, or other photopatternable polymers.

Optionally, the passivation layer 41 covers an upper surface, away from the carrier substrate 13, of the first type semiconductor layer 21. Optionally, the passivation layer 41 covers a side surface of the first reflective layer 31.

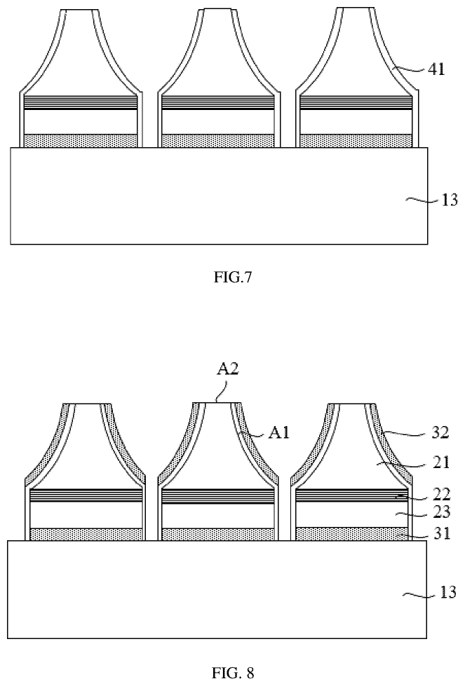

Step S6, as shown in FIG. 8, the first type semiconductor layer 21 includes a sloped wall A1 and an upper surface A2 on a side away from the carrier substrate 13. The sloped wall A1 matches the shape of the window 121, a second reflection layer is formed on the sloped wall A1, and the upper surface A2 is a light outlet.

It can be understood that the first type semiconductor layer 21 is epitaxially formed from the growth substrate with a relatively smaller area, which improves the crystal quality of the first type semiconductor layer and improves device reliability; in addition, the first type semiconductor layer 21 replicates the shape of the window 121 of the patterned mask layer 12, the resonant cavity light-emitting diode is formed at one time, without the need to use the process of etching the entire layer of the first type semiconductor to form a patterned unit, avoiding the etching process to the first type semiconductor layer, thereby ensuring that the crystal quality of the first type semiconductor layer is not reduced. Secondly, the first reflective layer 31 and the second reflective layer 32 constitute the resonant cavity of the resonant cavity light-emitting diode, and the light is reflected multiple times in the resonant cavity to improve the resonance effect of the light, so that the light has a narrower wavelength peak, improving the spectral purity; the second reflective layer 32 replicates the shape of the window 121 of the patterned mask layer 12, so that the upper surface A2 is the position where the cross-sectional area of the first type semiconductor layer is the smallest, that is, the area of the light outlet is the smallest, which can improve the directionality and collimation of light emission.

Optionally, the reflectivity of the second reflective layer 32 is lower than that of the first reflective layer 31, so that the upper surface A2 is a light outlet.

In an embodiment, the first type semiconductor layer 21 is n-type doped, and the second type semiconductor layer 23 is p-type doped.

In an embodiment, FIG. 9 is a schematic structural diagram of a resonant cavity light-emitting diode according to another embodiment of the present disclosure. As shown in FIG. 9, before placing the growth substrate 11, the patterned mask layer 12, the first type semiconductor layer 21, the active layer 22, the second type semiconductor layer 23 and the first reflective layer 31 upside down on the carrier substrate 13, the manufacturing method further includes: etching the first reflective layer 31 and part of the second type semiconductor layer 23 to form a second via hole, depositing an insulating layer 51 on an inner wall of the second via hole, forming, in the second via hole, a second electrode 62 electrically connected to the second type semiconductor layer 23, where the second electrode 62 is electrically connected to the driving circuit on the carrier substrate 13 and provides a driving signal for the second type semiconductor layer 23.

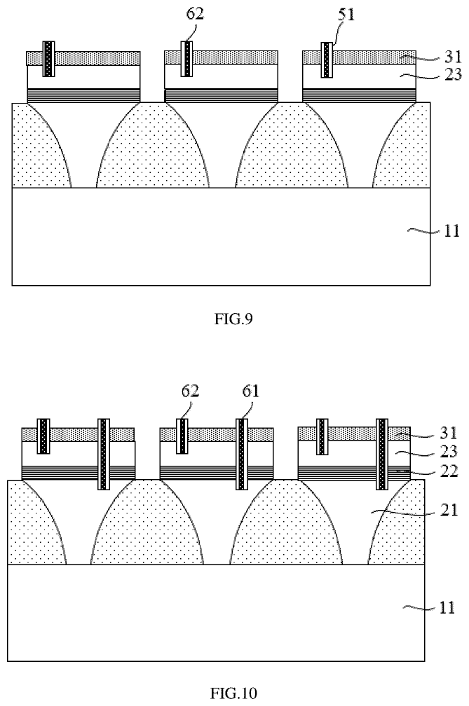

In an embodiment, FIG. 10 is a schematic structural diagram of a resonant cavity light-emitting diode according to another embodiment of the present disclosure, as shown in FIG. 10, while etching the second via hole, the first reflective layer 31, the second type semiconductor layer 23, the active layer 22 and part of the first type semiconductor layer 21 are etched to form a first via hole, and an insulation layer 51 is deposited on an inner wall of the first via hole and on an inner wall of the second via hole; a first electrode 61 electrically connected to the first type semiconductor layer 21 is formed in the first via hole, and a second electrode 61 electrically connected to the second type semiconductor layer 21 is formed in the second via hole. After being placed upside down on the carrier substrate 13, a resonant cavity light-emitting diode as shown in FIG. 11 is obtained. The first electrode 61 and the second electrode 62 provide driving signals for the first type semiconductor layer 21 and the second type semiconductor layer 23, respectively.

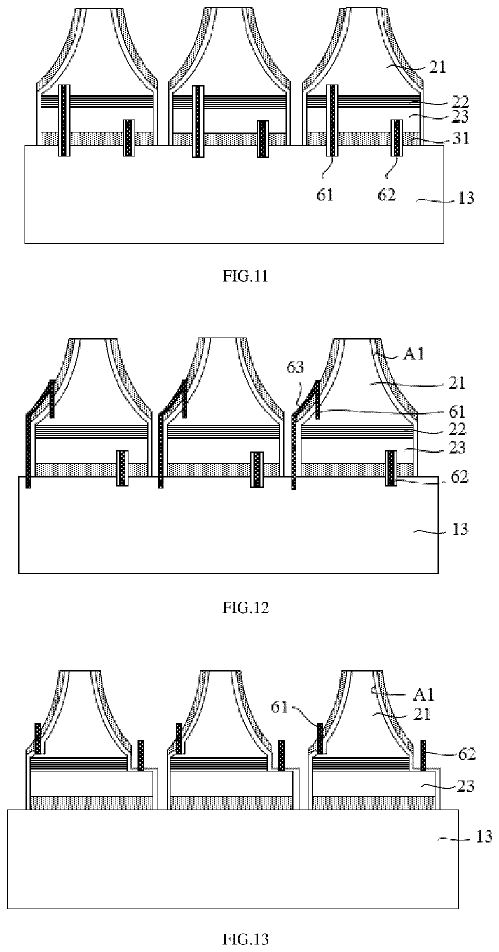

In an embodiment, FIG. 12 is a schematic structural diagram of a resonant cavity light-emitting diode according to another embodiment of the present disclosure. As shown in FIG. 12, after forming the second electrode 62 and placing the growth substrate 11, the patterned mask layer 12, the first type semiconductor layer 21, the active layer 22, the second type semiconductor layer 23 and the first reflective layer 31 upside down on the carrier substrate 13, the manufacturing method of the resonant cavity light-emitting diode further includes: etching the first type semiconductor layer 21 from the sloped wall A1 to form a first via hole, and forming, in the first via hole, a first electrode 61 electrically connected to the first type semiconductor layer 21. Optionally, the resonant cavity light-emitting diode further includes an electrode connecting wire 63 located on the side wall of each resonant cavity light-emitting diode, and the first type semiconductor layer 21 is electrically connected to the driving circuit on the carrier substrate 13 through the first electrodes 61 and the electrode connecting wire 63.

Optionally, the second electrode 62 is an interconnected common electrode, and the first electrode 61 is an independent electrode that provides an electrical signal separately for each resonant cavity light-emitting diode; or, the first electrode 61 is an interconnected common electrode, and the second electrode 62 is an independent electrode.

In an embodiment, FIG. 13 is a schematic structural diagram of a resonant cavity light-emitting diode according to another embodiment of the present disclosure. As shown in FIG. 13, in the resonant cavity light-emitting diode, the second electrode 62 is located on the surface of the second type semiconductor layer 23, the first electrode 61 is located on the sloped wall A1 of the first type semiconductor layer 21.

Based on the same inventive concept, the embodiment of the present disclosure also provides a resonant cavity light-emitting diode manufactured by any one of the above-mentioned manufacturing methods. As shown in FIG. 8, the resonant cavity light-emitting diode includes: a reflective layer 31, a second type semiconductor layer 23, an active layer 22 and a first type semiconductor layer 21 sequentially stacked on the carrier substrate 13; where the first type semiconductor layer 21 includes a sloped wall A1 and an upper surface A2 on the side away from the carrier substrate 13, along an arrangement direction of the carrier substrate 13 and the first type semiconductor layer 21, a cross-sectional area of the first type semiconductor layer 21 gradually decreases; and a second reflective layer 32, at least covering the sloped wall A1, and the upper surface A2 being a light outlet.

It should be noted that, in the resonant cavity light-emitting diode manufactured by the manufacturing method provided in the embodiment of the present disclosure, firstly, the first type semiconductor layer is epitaxially grown on the growth substrate with a relatively smaller area, then laterally epitaxially to fill the window, which can reduce the dislocation density and improve the crystal quality of the first type semiconductor layer; secondly, to form the resonant cavity light-emitting diode, there is no need to use the process of etching the entire layer of the first type semiconductor layer to form a patterned unit, avoiding the etching process to the first type semiconductor layer, thereby ensuring that the crystal quality of the first type of semiconductor layer is not reduced; moreover, the first reflective layer and the second reflective layer constitute the resonant cavity of the resonant light-emitting diode, and the light is reflected multiple times in the resonant cavity to improve the light resonance effect, so that the light has a narrower wavelength peak, improving the spectral purity; finally, the second reflective layer replicates the shape of the window of the patterned mask layer, so that the upper surface is the position where the cross-sectional area of the first type semiconductor layer is the smallest, that is, the area of the light outlet is the smallest, which improves the directionality and collimation of light emission.

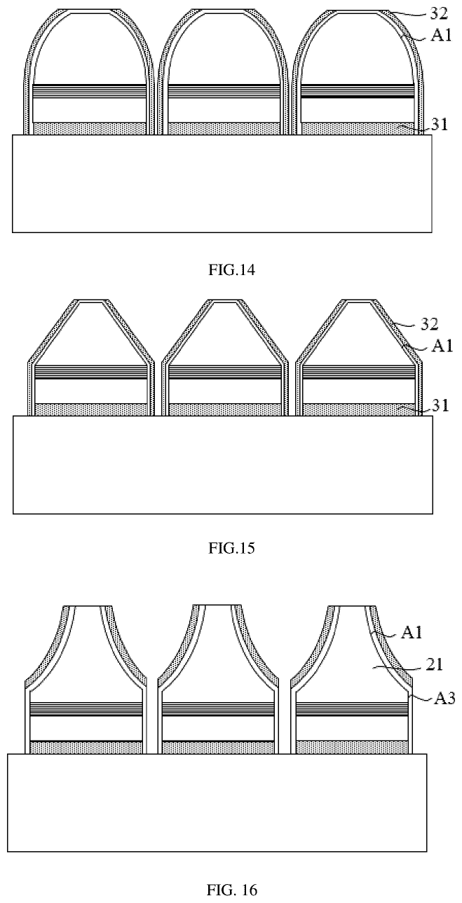

In an embodiment, in a direction perpendicular to the carrier substrate 13, the cross-sectional shape of the sloped wall A1 includes any one of a curve that is concave toward the carrier substrate 13, a curve that is protruding away from the carrier substrate 13, and a straight line, or a combination thereof. As shown in FIG. 8, the cross-sectional shape of the sloped wall A1 is a curve that is concave toward the carrier substrate 13. It can be understood that, the closer to the light outlet, the slope of the tangent line of the sloped wall A1 gradually increases, and the first type semiconductor layer 21 shows a tendency of gradual contraction, the light is more likely to be emitted upwards and toward the light outlet after being reflected by the side wall, which can speed up the escape of photons from the light outlet and improve the light extraction efficiency. FIG. 14 is a schematic structural diagram of a resonant cavity light-emitting diode according to another embodiment of the present disclosure. As shown in FIG. 14, the cross-sectional shape of the sloped wall A1 is a curve protruding away from the carrier substrate 13. FIG. 15 is a schematic structural diagram of a resonant cavity light-emitting diode according to another embodiment of the present disclosure. As shown in FIG. 15, the cross-sectional shape of the inclined wall A1 is a straight line.

Optionally, FIG. 16 is a schematic structural diagram of a resonant cavity light-emitting diode according to another embodiment of the present disclosure. As shown in FIG. 16, the side wall of the first type semiconductor layer 21 includes a sloped wall A1 and a vertical side wall A3. It can be understood that, in the manufacturing process, firstly, a first type semiconductor layer part in the window of the patterned mask layer is firstly epitaxially formed, then a first type semiconductor layer part in the vertical side wall A3 is epitaxially formed, at this time, the surface, away from the growth substrate, of the first type semiconductor layer is relatively flat, then the film layers of other semiconductor materials, such as the active layer 22 and the second type semiconductor layer 23, are epitaxially formed, which can improve the crystal quality of the film layers of other semiconductor materials, thereby improving the optoelectronic characteristics of the resonant cavity light-emitting diode.

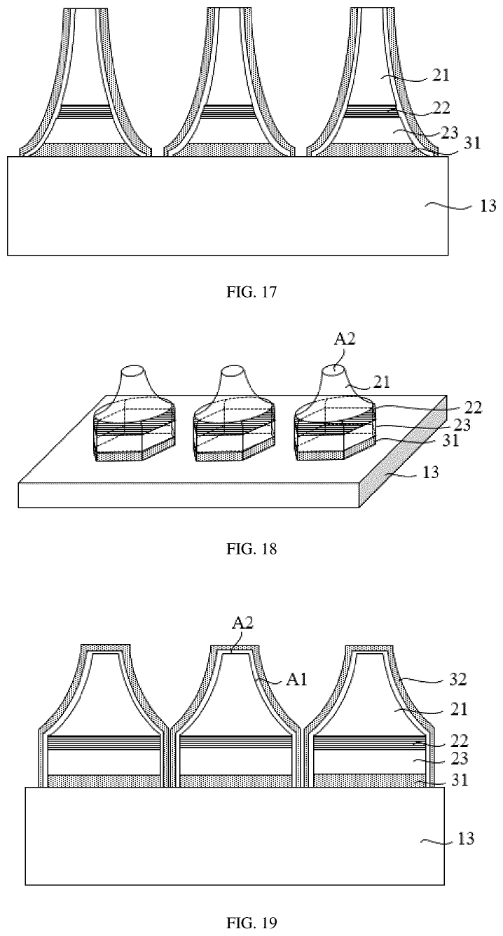

In an embodiment, FIG. 17 is a schematic structural diagram of a resonant cavity light-emitting diode according to another embodiment of the present disclosure. As shown in FIG. 17, along the arrangement direction of the carrier substrate 13 and the first type semiconductor layer 21, the cross-sectional area of the second type semiconductor layer 23, the active layer 22 and the first type semiconductor layer 21 is gradually decreased. Specifically, the closer to the light outlet, the second type semiconductor layer 23, the active layer 22 and the first type semiconductor layer 21 show a tendency to gradually converge, forming it easier for the light to be directed upward and toward the light outlet after being reflected on the side wall, which can speed up the photon escape from the light outlet and improve the light extraction efficiency.

In an embodiment, as shown in FIG. 8, the area of the upper surface A2 of the first type semiconductor layer 21 is 0.05˜0.5 times the cross-sectional area of the active layer 22. Specifically, the area of the upper surface A2 is the area of the light outlet, and the area of the active layer 22 is close to the projected area, on the carrier substrate 13, of the resonant cavity, the area of the light outlet should be as small as possible, which can improve the directionality and collimation of light emission; the area of the active layer 22 should be as large as possible, which can increase the number of photons and improve the internal quantum efficiency, after the light is reflected multiple times in the resonant cavity, the light extraction efficiency is improved. Optionally, the area of the upper surface A2 is 0.1 times, 0.2 times, 0.3 times or 0.4 times the area of the active layer 22.

In an embodiment, the shape of the upper surface A2 of the first type semiconductor layer 21 includes any one of a circle, an ellipse, or a polygon, and the shape of the surface, close to the carrier substrate 13, of the second type semiconductor layer 23 is a hexagon. FIG. 18 is a schematic three-dimensional structural diagram of a resonant cavity light-emitting diode according to an embodiment of the present disclosure. As shown in FIG. 18, the shape of the upper surface A2 is circular, and the shape of the surface, close to the carrier substrate 13, of the second type semiconductor layer 23 is hexagonal. It can be understood that, taking the epitaxial process of GaN as an example, GaN belongs to the hexagonal crystal system. When there is no limit of window of the patterned mask layer, the shape of GaN will gradually grow into a hexagon. It should be noted that FIG. 18 only illustrates the carrier substrate 13, the first reflective layer 31, the second type semiconductor layer 23, the active layer 22 and the first type semiconductor layer 21.

In an embodiment, FIG. 19 is a schematic structural diagram of a resonant cavity light-emitting diode according to another embodiment of the present disclosure. As shown in FIG. 19, the second reflective layer 32 also covers the upper surface A2 of the first type semiconductor layer 21, a side wall of the second type semiconductor layer 23 and a side wall of the active layer 22. Specifically, the second reflective layer 32 and the first reflective layer 31 form a nearly fully enclosed resonant cavity, which reduces the leakage of light from the side walls of the second type semiconductor layer 23 and the active layer 22, increases the reflection times of light in the resonant cavity, improves the light resonance effect, makes the light have a narrower wavelength peak, and improves the spectral purity.

In an embodiment, as shown in FIG. 19, the reflectivity of the second reflective layer located on the sloped wall A1 is higher than the reflectivity of the second reflective layer located on the upper surface A2. Specifically, the upper surface A2 with lower reflectivity is the light outlet, and the light is reflected multiple times in the resonant cavity formed by the first reflective layer 31 and the second reflective layer 32, and finally emerges from the upper surface A2. Optionally, the second reflective layer 32 is a distributed Bragg reflector composed of pairs of oxide materials. The period number of material pairs of the second reflective layer located on the sloped wall A1 is greater than that of the second reflective layer located on the upper surface A2. Optionally, the material of the second reflective layer located on the sloped wall A1 is different from the material of the second reflective layer located on the upper surface A2, where the reflectivity of the second reflective layer located on the inclined sloped A1 is higher.

In an embodiment, as shown in FIG. 11, the resonant cavity light-emitting diode also includes a driving circuit (not shown) located on the carrier substrate 13; a second electrode 62 located in the second via hole penetrating the first reflective layer 31 and part of the second type semiconductor 23, the second electrode 62 is used to electrically connect the second type semiconductor layer 23 and the driving circuit.

Optionally, as shown in FIG. 11, the resonant cavity light-emitting diode further includes a first electrode 61 located in the first via hole penetrating the first reflective layer 31, the second type semiconductor layer 23, the active layer 22 and part of the first type semiconductor layer 21. The first electrode 61 is used to electrically connect the first type semiconductor layer 21 and the driving circuit. Specifically, the first via hole for arranging the first electrode 61 and the second via hole for arranging the second electrode 62 can be etched and formed at the same time. The process is simple, and the first electrode 61 and the second electrode 62 do not affect the light output and improve the light extraction efficiency. It should be noted that an insulating layer 51 is firstly formed in the first via hole and the second via hole, and then the electrode structure is formed.

In an embodiment, as shown in FIG. 12, the second electrode of the resonant cavity light-emitting diode is located in the second via hole between the second type semiconductor layer 23 and the carrier substrate 13. The resonant cavity light-emitting diode further includes: a first electrode 61, located in the first via hole of the sloped wall A1; an electrode connection line 63, located at the sloped wall A1, the side wall of the active layer 22 and the side wall of the second type semiconductor layer 23. The first type semiconductor layer 21 is electrically connected to the driving circuit through the first electrode 61 and the electrode connection line 63. Specifically, the electrode structure does not penetrate the active layer 22, does not reduce the area of the active layer, fully retains the space where electrons and holes can be excited, and improves light extraction efficiency.

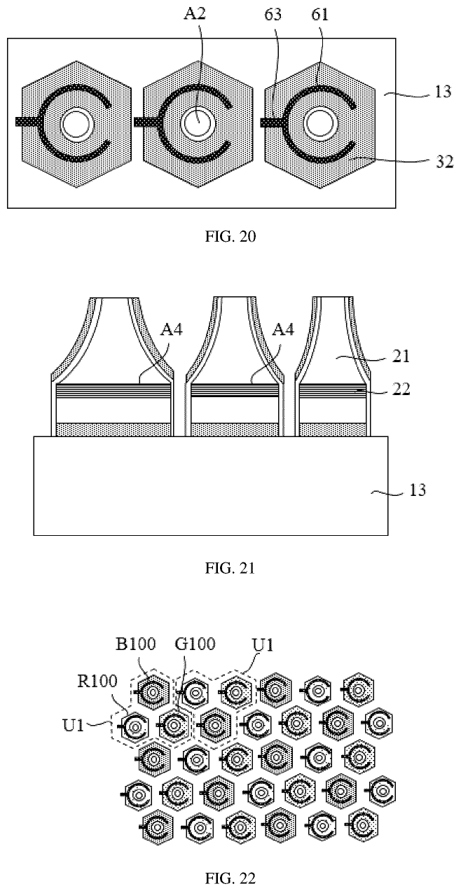

Optionally, FIG. 20 is a top view of the resonant cavity light-emitting diode provided in FIG. 12. As shown in FIG. 20, in order to reduce the contact resistance between the first electrode 61 and the first type semiconductor layer 21, the first electrode 61 is an arc shape with more than 180 degrees. The first electrode 61 is electrically connected to the drive circuit on the carrier substrate 13 through the electrode connection line 63. It should be noted that the outer contour of the second reflective layer 32 shown in FIG. 20 is a hexagon, which means that the projection shape, on the carrier substrate 13, of the second type semiconductor layer 23 is a hexagon; the projection shape, on the carrier substrate 13, of the upper surface A2 of the first type semiconductor layer 21 is circular.

In an embodiment, FIG. 21 is a schematic structural diagram of a resonant cavity light-emitting diode according to another embodiment of the present disclosure. As shown in FIG. 21, the first type semiconductor layer 21 also includes a lower surface A4 close to the active layer 22, there are at least two resonant cavity light-emitting diodes with different areas of the lower surfaces A4, so that the two resonant cavity light-emitting diodes have different emission wavelengths. It should be noted that, taking the material of the active layer 22 being InGaN/GaN as an example, the areas of the lower surfaces A4 of the two resonant cavity light-emitting diodes are different, and the areas of the subsequent epitaxial active layers 22 are different. Due to the different incorporation rates of In component in the active layers with different areas, the two finally produced resonant cavity light-emitting diodes have different emission wavelengths. Optionally, the larger the area of the lower surface A4, the shorter the emission wavelength of the resonant cavity light-emitting diode.

Optionally, FIG. 22 is an arrangement diagram of resonant cavity light-emitting diodes according to an embodiment of the present disclosure. As shown in FIG. 22, the resonant cavity light-emitting diodes R100/G100/B100 respectively emit red light, green light and blue light. Each pixel unit U1 includes one R100, one G100 and one B100, and forms a delta arrangement. Optionally, the resonant cavity light-emitting diodes can also be configured in either a standard red, green, blue (RGB) arrangement or a diamond-shaped arrangement.

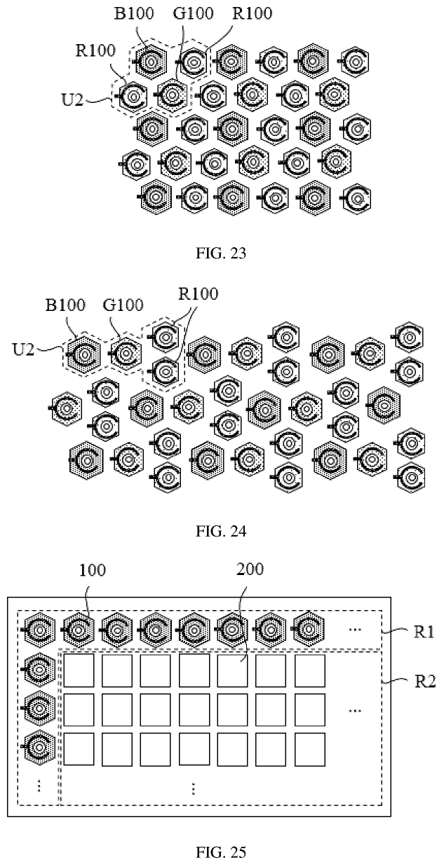

Optionally, considering that the luminous efficiency of red light is lower compared to the luminous efficiency of green light and blue light, one pixel unit may include multiple resonant cavity light-emitting diodes that emit red light to balance the three-color ratio in a pixel unit. FIG. 23 is an arrangement diagram of resonant cavity light-emitting diodes according to another embodiment of the present disclosure. FIG. 24 is an arrangement diagram of resonant cavity light-emitting diodes according to another embodiment of the present disclosure. As shown in FIG. 23 and FIG. 24, the resonant cavity light-emitting diodes R100/G100/B100 respectively emit red light, green light and blue light. Each pixel unit U2 includes two R100s, one G100 and one B100. Among them, as shown in FIG. 23, in one pixel unit U2, two R100s, one G100 and one B100 are presented as a staggered arrangement; as shown in FIG. 24, in one pixel unit U2, two R100s, one G100 and one B100 are presented as a standard RGB arrangement.

Based on the same inventive concept, an embodiment of the present disclosure also provides a light-emitting array structure. FIG. 25 is a schematic structural diagram of a light-emitting array structure according to an embodiment of the present disclosure. As shown in FIG. 25, the light-emitting array structure includes: a first light-emitting area R1 and a second light-emitting area R2 that are adjacent, the first light-emitting area R1 includes the above-mentioned resonant cavity light-emitting diodes 100, and a pixel structure 200 of the second light-emitting area R2 includes any one of LED pixels, OLED pixels or LCD pixels.

Optionally, the resonant cavity light-emitting diode emits visible light, and the pixel structure is used as a display screen. The arrangement of the resonant cavity light-emitting diodes 100 and the arrangement of the pixel structure 200 include any one of a standard RGB arrangement, a delta arrangement or a diamo

nd arrangement. Compared with LED pixels, OLED pixels and LCD pixels, the resonant cavity light-emitting diode disclosed in this disclosure can improve light extraction efficiency, brightness and color. In traditional light-emitting array structure, there is a problem of low brightness in a frame area. The light-emitting array structure provided by this disclosure can be provided with the first light-emitting area in the frame area and the second light-emitting area in a center area to improve the brightness uniformity of the light-emitting array structure.

Optionally, LED (Light-Emitting Diode) pixels include micro-LED pixels, mini-LED pixels or conventional LED pixels, and OLED (Organic Light-Emitting Diode) pixels include PMOLED (Passive-matrix OLED) pixels or AMOLED (Active-matrix OLED) pixels, etc.

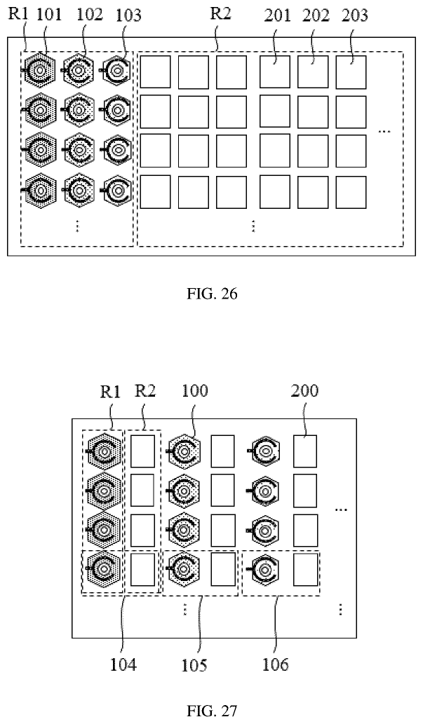

Optionally, FIG. 26 is a schematic structural diagram of a light-emitting array structure according to another embodiment of the present disclosure. As shown in FIG. 26, the first light-emitting area R1 includes resonant cavity light-emitting diodes 101/102/103 that respectively emit blue light, green light, and red light, the second light-emitting area R2 includes a pixel structure 201/202/203 that emits blue light, green light, and red light respectively, the color arrangement of the resonant cavity light-emitting diodes 101/102/103 is the same with the color arrangement of the pixel structure 201/202/203, which belongs to the standard RGB arrangement.

Optionally, FIG. 27 is a schematic structural diagram of a light emitting array structure according to another embodiment of the present disclosure. As shown in FIG. 27, the first light-emitting area R1 and the second light-emitting area R2 are alternately arranged in the row direction, and a resonant cavity light-emitting diode 100 is provided on one side of each pixel structure 200 to improve the problem of low brightness of the pixel structure 200. Optionally, as shown in FIG. 27, a blue sub-pixel 104 includes a resonant cavity light-emitting diode 100 that emits blue light and a pixel structure 200 that emits blue light, a green sub-pixel 105 includes a resonant cavity light-emitting diode that emits green light 100 and a pixel structure 200 that emits green light, and a red sub-pixel 106 includes a resonant cavity light-emitting diode 100 that emits red light and a pixel structure 200 that emits red light.

Optionally, the light-emitting array structure is applied to display devices, such as mobile phones, where the resonant cavity light-emitting diode emits infrared light for fingerprint unlocking, and the pixel structure emits visible light for displaying pictures.

Those skilled in the art may combine and integrate different embodiments or examples described in this specification, as well as features from different embodiments or examples unless they are inconsistent with each other. The above are only preferred embodiments of the present disclosure and are not intended to limit the present disclosure. Any modifications, equivalent substitutions, etc. made within the spirit and principles of the present disclosure shall be included in the protection scope of the present disclosure.

What is claimed is:

1. A manufacturing method of a resonant cavity light-emitting diode, comprising:
forming a patterned mask layer on a growth substrate, wherein the patterned mask layer has a window exposing the growth substrate, along an arrangement direction of the growth substrate and the patterned mask layer, a cross-sectional area of the window gradually increases;
epitaxially forming a first type semiconductor layer in the window;
epitaxially forming an active layer, a second type semiconductor layer and a first reflective layer on the first type semiconductor layer;
placing the growth substrate, the patterned mask layer, the first type semiconductor layer, the active layer, the second type semiconductor layer and the first reflective layer upside down on a carrier substrate;
removing the growth substrate and the patterned mask layer, wherein a cross-sectional area of the first type semiconductor layer gradually decreases along an arrangement direction of the carrier substrate and the first type semiconductor layer, the first type semiconductor layer comprises a sloped wall and an upper surface on a side away from the carrier substrate, and the sloped wall matches a shape of the window; and
forming a second reflection layer on the sloped wall, the upper surface being a light outlet.

2. The manufacturing method according to claim 1, wherein after removing the growth substrate and the patterned mask layer, the manufacturing method further comprises:
forming a passivation layer on a side wall of the first type semiconductor layer, the active layer and the second type semiconductor layer.

3. The manufacturing method according to claim 1, wherein before placing the growth substrate, the patterned mask layer, the first type semiconductor layer, the active layer, the second type semiconductor layer and the first reflective layer upside down on the carrier substrate, the manufacturing method further comprises:
etching the first reflective layer and part of the second type semiconductor layer to form a second via hole;
depositing an insulating layer on an inner wall of the second via hole; and
forming, in the second via hole, a second electrode electrically connected to the second type semiconductor layer.

4. The manufacturing method according to claim 3, further comprising:
while etching the second via hole, etching the first reflective layer, the second type semiconductor layer, the active layer and part of the first type semiconductor layer to form a first via hole,
depositing an insulating layer on an inner wall of the first via hole; and
forming, in the first via hole, a first electrode electrically connected to the first type semiconductor layer.

5. The manufacturing method according to claim 3, wherein after placing the growth substrate, the patterned mask layer, the first type semiconductor layer, the active layer, the second type semiconductor layer and the first reflective layer upside down on the carrier substrate, the manufacturing method further comprises:
etching the first type semiconductor layer from the sloped wall to form a first via hole, and forming, in the first via hole, a first electrode electrically connected to the first type semiconductor layer.

6. A resonant cavity light-emitting diode manufactured according to the manufacturing method of claim 1, comprising:
a first reflective layer, a second type semiconductor layer, an active layer and a first type semiconductor layer sequentially stacked on a carrier substrate; wherein the first type semiconductor layer comprises a sloped wall and an upper surface on a side away from the carrier substrate, along an arrangement direction of the carrier substrate and the first type semiconductor layer, a cross-sectional area of the first type semiconductor layer gradually decreases; and
a second reflective layer, at least covering the sloped wall, and the upper surface being a light outlet.

7. The resonant cavity light-emitting diode according to claim 6, wherein in a direction perpendicular to the carrier substrate, a cross-sectional shape of the sloped wall comprises any one of a curve that is concave toward the carrier substrate, a curve that is protruding away from the carrier substrate, and a straight line, or a combination thereof.

8. The resonant cavity light emitting diode according to claim 6, wherein along the arrangement direction of the carrier substrate and the first type semiconductor layer, a cross-sectional area of the second type semiconductor layer, the active layer and the first type semiconductor layer gradually decreases.

9. The resonant cavity light-emitting diode according to claim 6, wherein an area of the upper surface of the first type semiconductor layer is 0.05 to 0.5 times a cross-sectional area of the active layer.

10. The resonant cavity light-emitting diode according to claim 6, wherein a shape of the upper surface of the first type semiconductor layer comprises any one of a circle, an ellipse, or a polygon.

11. The resonant cavity light-emitting diode according to claim 6, wherein a shape of a surface, close to the carrier substrate, of the second type semiconductor layer is hexagonal.

12. The resonant cavity light-emitting diode according to claim 6, wherein the second reflective layer also covers the upper surface of the first type semiconductor layer, a side wall of the second type semiconductor layer and a side wall of the active layer.

13. The resonant cavity light-emitting diode according to claim 12, wherein a reflectivity of the second reflective layer located on the sloped wall is higher than a reflectivity of the second reflective layer located on the upper surface.

14. The resonant cavity light-emitting diode according to claim 6, further comprising:
a driving circuit, located on the carrier substrate; and
a second electrode, located in a second via hole that penetrates the first reflective layer and part of the second type semiconductor layer, the second electrode being used to electrically connect the second type semiconductor layer and the driving circuit.

15. The resonant cavity light-emitting diode according to claim 14, further comprising:
a first electrode, located in a first via hole that penetrates the first reflective layer, the second type semiconductor layer, the active layer and part of the first type semiconductor layer, the first electrode being used to electrically connect the first type semiconductor layer and the driving circuit.

16. The resonant cavity light-emitting diode according to claim 14, further comprising:
a first electrode, located in a first via hole of the sloped wall; and
an electrode connection line, located on the sloped wall, a side wall of the active layer and a side wall of the second type semiconductor layer, wherein the first type semiconductor layer is electrically connected to the drive circuit through the first electrode and the electrode connection line.

17. The resonant cavity light-emitting diode according to claim 6, wherein the first type semiconductor layer further comprises a lower surface close to the active layer,
at least two resonant cavity light-emitting diodes have different areas of the lower surfaces, so that the two resonant cavity light-emitting diodes have different emission wavelengths.

18. A light-emitting array structure, comprising: a first light-emitting area and a second light-emitting area that are adjacent,
the first light-emitting area comprising the resonant cavity light-emitting diode according to claim 6; and
a pixel structure of the second light-emitting area comprising any one of light-emitting diode (LED) pixels, organic light emitting diode (OLED) pixels or liquid crystal display (LCD) pixels.

19. The light-emitting array structure according to claim 18, wherein the first light-emitting area is arranged in a frame area, and the second light-emitting area is arranged in a central area; or the first light-emitting area and the second light-emitting area are arranged alternately in a row direction.

20. The light-emitting array structure according to claim 18, wherein an arrangement of the resonant cavity light-emitting diode and an arrangement of the pixel structure comprise any one of a standard red, green, blue (RGB) arrangement, a delta arrangement or a diamond arrangement.
